(19) United States
(12) Patent Application Publication
(10) Pub. No.: US 2026/0145563 A1
(43) Pub. Date: May 28, 2026

(54) CHARGING DEVICE

(71) Applicant: LG ELECTRONICS INC., Seoul (KR)

(72) Inventors: Kangsuk LEE, Seoul (KR); Jiho LEE, Seoul (KR); Junyeop JEONG, Seoul (KR); Sunghwan OH, Seoul (KR); Myoungku LEE, Seoul (KR)

(73) Assignee: LG ELECTRONICS INC., Seoul (KR)

(21) Appl. No.: 19/053,316

(22) Filed: Feb. 13, 2025

(30) Foreign Application Priority Data
Nov. 22, 2024 (WO) PCT/KR2024/018628

(51) Int. Cl. B60L 53/31; B60L 53/66; H05K 5/02; H05K 9/00

(52) U.S. Cl. CPC B60L 53/31; B60L 53/665; H05K 5/0247; H05K 9/0009; H05K 9/0015

(57) ABSTRACT

Disclosed is a charging device including a main body having a cable connected charger located therein, a front door covering a front surface of the main body and portions of both side surfaces of the main body, a pair of side covers covering the rest of the both side surfaces of the main body, a rear cover covering a rear surface of the main body, and an antenna disposed on an upper surface of the main body, wherein the upper surface of the main body is formed lower than upper surfaces of the front door, a pair of the side covers, and the rear cover.

### CROSS-REFERENCE TO RELATED APPLICATION(S)

Pursuant to 35 U.S.C. § 119(a), the present application claims the benefit of earlier filing date and right of priority to the International Application No. PCT/KR 2024/018628, filed on Nov. 22, 2024, the contents of which are all incorporated by reference herein in their entirety.

### BACKGROUND OF THE DISCLOSURE

### Field of the Disclosure

The present embodiments relate to a charging device, and more particularly, to a charging device that prevents exterior exposure of an antenna.

### Discussion of the Related Art

In general, Electric Vehicles (EVs) have not been put to practical use for a long time due to problems such as heavy weight of a battery mounted in a vehicle and a charging time of the battery and the like compared to gasoline or diesel vehicles. However, due to the recent depletion of fossil energy and environmental pollution, research and development have been actively conducted as interest in electric vehicles that do not use fossil energy and use electric energy has increased.

As a result, the spread of electric vehicles is increasing in recent years. An electric vehicle includes a battery that supplies power for driving, and has a structure in which power is stored in the battery. Therefore, in order to continuously operate the electric vehicle, the battery should be charged. Accordingly, an infrastructure for charging an electric vehicle is required, and fixedly installed standing charging facilities are being provided in various places to meet the increasing demand for electric vehicles.

In particular, the charging device requires approval using communication for payment, etc., and thus is provided with an antenna and a modem for this purpose. Due to the characteristics of the antenna and the modem, the modem may be provided inside the charging device, but since the antenna for wireless radiation needs to be provided in an externally exposed state, there is a problem in that the aesthetic design is deteriorated.

### SUMMARY OF THE DISCLOSURE

One object of the present disclosure is to provide a charging device that prevents exposure of an antenna in appearance by forming a step difference in an area where the antenna is installed.

Another object of the present disclosure is to provide a charging device that prevents water retention from occurring in a step by forming a water discharge passage.

Additional advantages, objects, and features of the disclosure will be set forth in the disclosure herein as well as the accompanying drawings. Such aspects may also be appreciated by those skilled in the art based on the disclosure herein.

To achieve these objects and other advantages and in accordance with the purpose of the disclosure, as embodied and broadly described herein, a charging device according to the present disclosure may include a main body having a cable connected charger located therein, a front door covering a front surface of the main body and portions of both side surfaces of the main body, a pair of side covers covering the rest of the both side surfaces of the main body, a rear cover covering a rear surface of the main body, and an antenna disposed on an upper surface of the main body, wherein the upper surface of the main body may be formed lower than upper surfaces of the front door, a pair of the side covers, and the rear cover.

The upper surfaces of the front door, a pair of the side covers, and the rear cover may be formed in the same plane.

The charging device may further include a stand coupled to the upper surface of the main body and having a height to support a lower portion of the antenna, and a sum of a height of the stand and a height of the antenna may be equal to a height from the upper surface of the main body to the upper surface of the front door, a pair of the side covers, or the rear cover.

A portion of the upper surface of the stand meeting the lower portion of the antenna and a portion of the upper surface of the main body meeting a lower portion of the stand may include a sealing member.

The charging device of may further include a first space formed by the upper surface of the main body and inner surfaces of the front door, a pair of the side covers, and the rear cover.

The charging device may further include an upper cover disposed on the main body and having an accommodation space for receiving the antenna therein to expose the antenna externally.

The upper cover may include an antenna hole formed to make a step difference from an upper surface of the upper cover and an inclined surface extending from a circumference forming the antenna hole to the upper surface of the upper cover toward an outer direction, and the accommodation space may be formed by the antenna hole and the inclined surface.

The antenna hole may be formed in the same plane as the lower portion of the antenna.

The front door may include a door part in a plate shape coupled to a front surface of the main body and a bent part extending from both sides of the door part in a direction of surrounding the both side surfaces of the main body, and the bent part may be spaced apart from the side surface of the main body.

The charging device may further include a second space formed by the door part, the bent part and the side surface of the main body.

An upper edge and side edges of the both sides forming a flange of the front surface of the main body may include preventive projections protruding from the upper surface of the main body and the side surface of the main body, respectively.

The preventive projection may include a sealing member.

The charging device may further include a locking part located on the upper surface of the main body.

The charging device may further include a support part coupled to the lower portion of the main body, and the support part may include a discharge hole formed in an area meeting the front door not to be externally exposed by the front door.

According to embodiments, the aesthetics of a charging device may be improved by providing the charging device that prevents exposure of an antenna in appearance by forming a step difference in an area where the antenna is installed.

According to embodiments, it is possible to prevent damage caused by moisture in a charging device by providing the charging device that prevents water retention from occurring in a step by forming a water discharge passage.

The effects obtained by the present disclosure are not limited to the above-mentioned effects, and other effects not mentioned will be clearly understood by those skilled in the art to which the present disclosure pertains from the following description

It is to be understood that both the foregoing general description and the following detailed description of the present disclosure are exemplary and explanatory and are intended to provide further explanation of the disclosure as claimed.

### BRIEF DESCRIPTION OF THE DRAWINGS

FIG. 1 is a diagram illustrating a charging device according to embodiments.

FIG. 2 is an exploded diagram illustrating a part A of the charging device shown in FIG. 1.

FIGS. 3 and 4 are diagrams illustrating a state in which an upper cover of a charging device according to embodiments is removed.

FIG. 5 is a diagram illustrating a state in which an upper cover of a charging device according to embodiments is coupled.

FIGS. 6 and 7 are diagrams illustrating a cross section in a direction A-A′ of FIG. 5.

FIGS. 8 and 9 are diagrams illustrating a second space of a charging device according to embodiments.

FIG. 10 is a diagram illustrating a path where water moves along a second space of a charging device according to embodiments.

FIG. 11 is a diagram illustrating a lower portion of a charging device according to embodiments

### DETAILED DESCRIPTION OF THE DISCLOSURE

Description will now be given in detail according to exemplary embodiments disclosed herein, with reference to the accompanying drawings. The same or equivalent components may be provided with the same reference numbers, and description thereof will not be repeated. As used herein, the suffixes “module” and “part” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification. As such, the present disclosure should be construed to extend to any alterations, equivalents and substitutes in addition to those which are particularly set out in the accompanying drawings.

Although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, it will be understood that when an element is referred to as being “directly connected with” another element, there are no intervening elements present.

A singular representation may include a plural representation unless it represents a definitely different meaning from the context.

The terms such as “include” or “have” used herein are intended to indicate that features, numbers, steps, operations, elements, components, or combinations thereof used in the following description exist and it should be thus understood that the possibility of existence or addition of one or more different features, numbers, steps, operations, elements, components, or combinations thereof is not excluded.

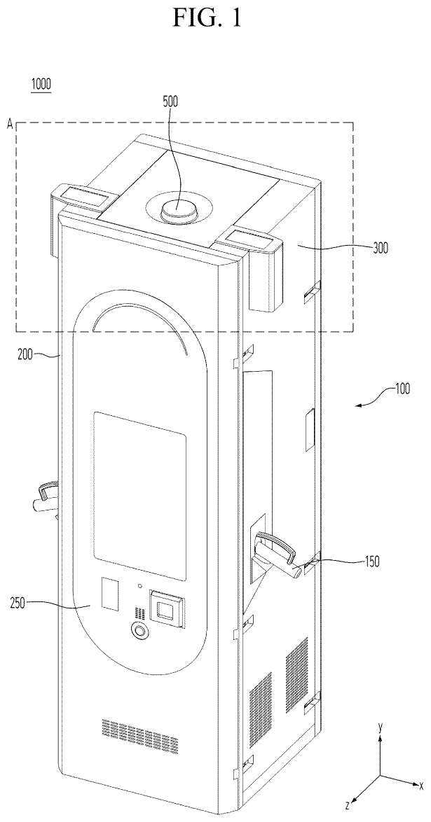

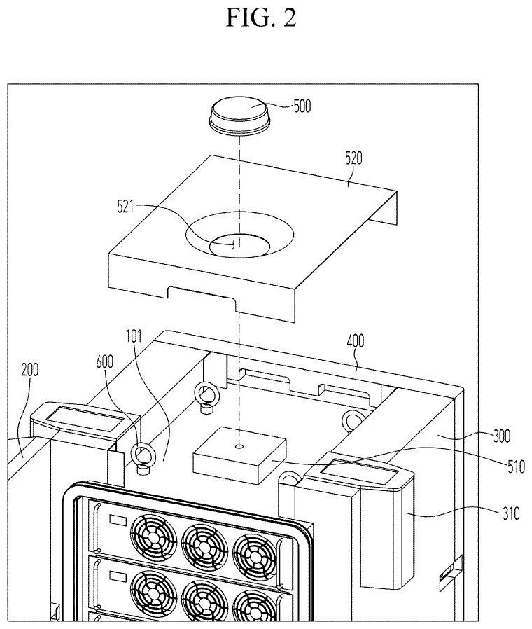

FIG. 1 is a diagram illustrating a charging device according to embodiments. FIG. 2 is an exploded diagram illustrating a part A of the charging device illustrated in FIG. 1.

Hereinafter, in describing a charging device 1000 according to embodiments, a horizontal direction is described based on an x-axis direction, a vertical direction is described based on a y-axis direction, and a direction toward a front surface or a rear surface is described based on a z-axis direction.

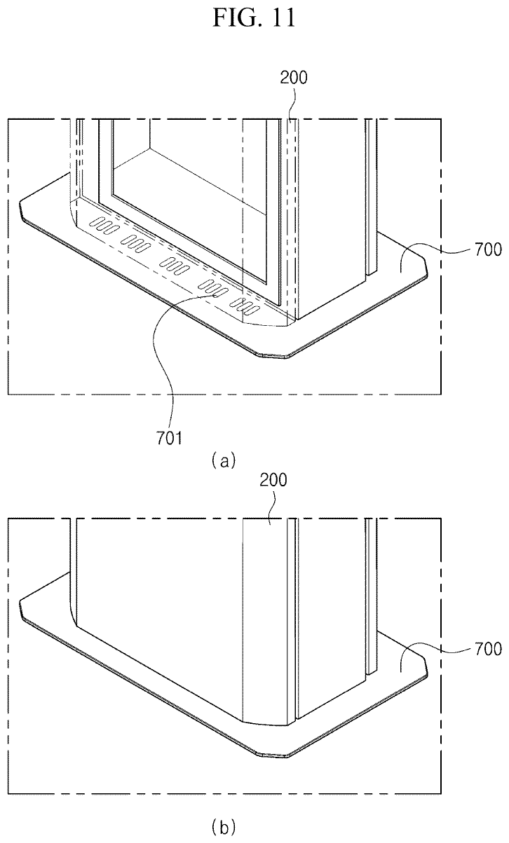

Referring to FIGS. 1 and 2, the charging device 1000 according to embodiments may include a main body 100, a front door 200, a side cover 300, a rear cover 400, an antenna 500, a locking part 600, a support part 700, and the like. The support part 700 will be described in FIG. 11.

The charging device 1000 according to the embodiments may be a type of device for charging an Electric Vehicle (EV). More specifically, the charging device 1000 according to the embodiments may correspond to an EV charger dispenser, which is one of devices used when charging the electric vehicle. A dispenser is a device that stores and protects a charging cable, and is generally installed in combination with a charger, and a user may pull the cable connected to the charger from the dispenser and connect the cable to the electric vehicle.

A charger 150 to which a cable is connected is positioned in the main body 100, and an LED indicator or screen indicating a charging state may be built in the main body 100. As illustrated in FIG. 1 and FIG. 2, the main body 100 may have a rectangular parallelepiped shape, and the front door 200, the side cover 300, and the rear cover 400 may cover a circumference thereof.

The front door 200 is configured to cover a front surface and a portion of a side surface 102 of the main body 100, and may display an LED indicator, a screen, and the like indicating a charging state. The rear cover 400 is configured to cover a rear surface of the main body 100.

The side cover 300 is configured to cover the remainder of the side surface 102 of the main body 100, and may be provided in a pair on both sides of the main body 100. A retractor 310 may be positioned inside the side cover 300. The retractor 310 is a device that safely stores a charging cable and helps a user to use the retractor 310 conveniently, and the side cover 300 for storing the retractor 310 may cover the entire side surface 102 of the main body 100 as shown in FIGS. 1 and 2.

The antenna 500 is a configuration located on an upper surface of the main body 100, which may correspond to a configuration in which an electric signal is converted into wireless radio waves and transmitted, and conversely, wireless radio waves are converted into an electric signal and received. In particular, the charging device 1000 may utilize communication for payment or the like, and may include the antenna 500 and a modem for such communication. In this case, the modem may be provided inside the main body 100, but the antenna 500 may be provided in a state of being exposed to the outside for wireless radiation.

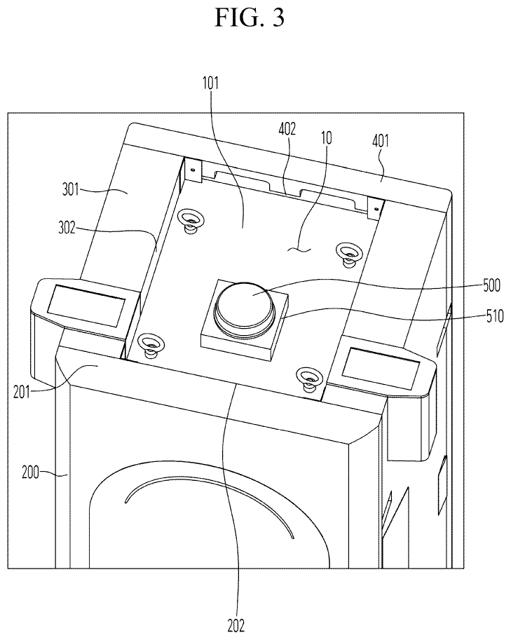

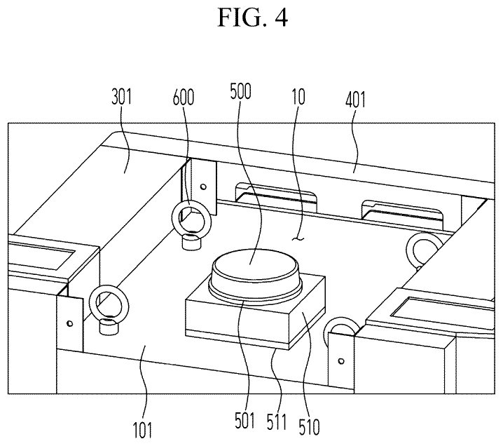

In the related art charging device, there is a problem in that the antenna 500 is exposed externally so as to deteriorate the aesthetics. Accordingly, in the charging device 1000 according to embodiments, the upper surface of the main body 100 may be lower than the upper surfaces of the front door 200, the side cover 300, and/or the rear cover 400 so that the antenna 500 is not exposed to the outside. A detailed description thereof will be described with reference to FIGS. 3 and 4.

Like the antenna 500, the locking part 600 is configured to be located on the upper surface of the main body 100 and may include a fixing portion and a ring portion. The fixing portion may be located inside the main body 100. More specifically, the fixing portion may be fixed and/or coupled to a receiving recess formed in the upper surface of the main body 100. The ring portion may be coupled to the fixing portion and may be located outside the main body 100. That is, the fixing portion may be inserted into the upper surface of the main body 100 and may be located inside the main body 100, and the ring portion may be located outside.

The charging device 1000 according to embodiments may be moved through the locking part 600. That is, the charging device 1000 may be moved to another place by hanging a string, a rope, or the like on the ring portion of the locking part 600. The locking part 600 may be a kind of eyebolt.

In the related art charging device, there is a problem in that the locking part 600 is exposed to the outside, thereby deteriorating aesthetic design. Accordingly, in the charging device 1000 according to embodiments, the upper surface of the main body 100 may be formed to be lower than the upper surfaces of the front door 200, the side cover 300, and/or the rear cover 400 so that the locking part 600 is not exposed to the outside. A detailed description thereof will be described with reference to FIGS. 3 and 4.

FIGS. 3 and 4 are diagrams illustrating a state in which an upper cover of a charging device according to embodiments is removed.

Referring to FIG. 3 and FIG. 4, an upper surface 101 of the main body 100 may be formed to be lower than an upper surface 202 of the front door 200, an upper surface 301 of the side cover 300, and/or an upper surface 401 of the rear cover 400. In other words, the main body 100 may be positioned such that a step difference is formed from each of the front door 200, the side cover 300, and/or the rear cover 400.

The upper surface 202 of the front door 200, the upper surface 301 of the side cover 300, and the upper surface 401 of the rear cover 400 may be formed in the same plane. In other words, the upper surface 201 of the front door 200, the upper surface 301 of the side cover 300, and the upper surface 401 of the rear cover 400 may form one plane, i.e., have the same height.

In addition, a length from the upper surface 101 of the main body 100 to the upper surface 201 of the front door 200, a length from the upper surface 101 of the main body 100 to the upper surface 301 of the side cover 300, and a length from the upper surface 101 of the main body 100 to the upper surface 401 of the rear cover 400 may be formed greater than the height of the antenna 500.

More specifically, as illustrated in FIGS. 3 and 4, the charging device 1000 according to embodiments may further include a stand 510, and the antenna 500 may be disposed on an upper surface of the stand 510. That is, the stand 510 may be formed to have a height so as to be coupled to the upper surface of the main body 100 and to support a lower portion of the antenna 500. Also, the sum of the height of the stand 510 and a height of the antenna 500 may be the same as the length from the upper surface 101 of the main body 100 to the upper surface 201 of the front door 200, the length from the upper surface 101 of the main body 100 to the upper surface 301 of the side cover 300, or the length from the upper surface 101 of the main body 100 to the upper surface 401 of the rear cover 400.

Therefore, since the antenna 500 of the charging device 1000 according to the embodiments is located in a first space 10 formed by the front door 200, the side cover 300, and the rear cover 400, it may not be recognized based on the appearance.

Likewise, since the locking part 600 of the charging device 1000 according to the embodiments is also located in the first space 10 formed by the front door 200, the side cover 300, and the rear cover 400, it may not be recognized based on the appearance.

More specifically, the first space 10 may be formed by the upper surface 101 of the main body 100, an inner surface 202 of the front door 200, inner surfaces 302 of a pair of the side covers 300, and an inner surface 402 of the rear cover 400. That is, the antenna 500 may be located in the first space 10 having a rectangular parallelepiped shape to be formed. Since four surfaces of the first space 10 are formed by the front door 200, the side cover 300, and the rear cover 400, as a result, the antenna 500 may not be recognized based on appearance.

Likewise, the locking part 600 may also be located in the rectangular parallelepiped-shaped first space 10 to be formed, and the first space 10 may have four surfaces made up of the front door 200, the side cover 300, and the rear cover 400, so the locking part 600 may not be recognized based on the appearance through the four surfaces.

Accordingly, there is an effect that the antenna 500 and the locking part 600 of the charging device 1000 according to embodiments are not exposed to a user.

Also, referring to FIG. 4, a portion of the upper surface of the stand 510 that meets the lower portion of the antenna 500 and a portion of the upper surface 101 of the main body 100 that meets a lower portion of the stand 510 may include sealing members 501 and 511, respectively. That is, the charging device 1000 according to embodiments may include the sealing member 501 formed along a portion where the stand 510 meets the antenna 500, and more particularly, along a circumference of a lower surface of the antenna 500. In other words, the circumference of the lower surface of the antenna 500 may be formed of the sealing member 501.

Likewise, the charging device 1000 according to embodiments may include the sealing member 511 formed along a portion where the stand 510 and the main body 100 meet each other, and more particularly, along the circumference of the lower surface of the stand 510. In other words, the circumference of the lower surface of the stand 510 may be formed of the sealing member 511.

Therefore, even when water penetrates into the first space 10 due to rain, snow, etc., the formed sealing members 501 and 511 may prevent the antenna 500 of the charging device 1000 according to the embodiments from being damaged due to moisture.

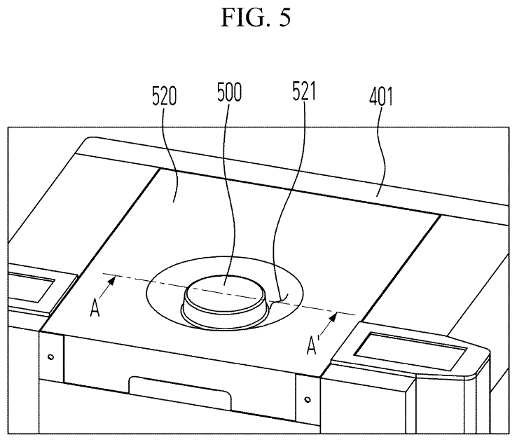

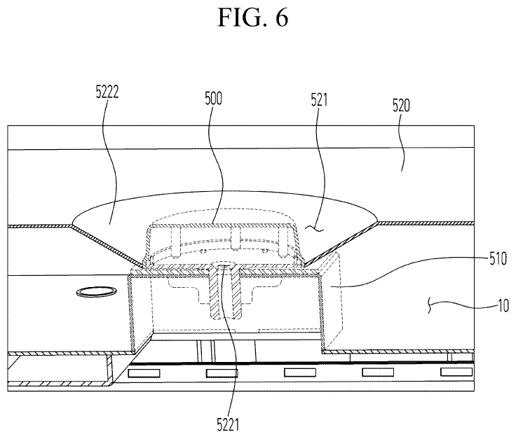

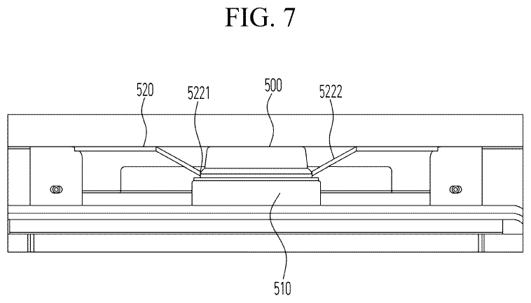

FIG. 5 is a diagram illustrating a coupled state of an upper cover of a charging device according to embodiments. FIGS. 6 and 7 are diagrams illustrating a cross section taken along a direction A-A′ of FIG. 5.

Referring to FIGS. 5 to 7, the charging device 1000 according to embodiments may include an upper cover 520.

The upper cover 520 may be disposed on an upper portion of the main body 100, and an accommodation space 521 configured to accommodate the antenna 500 so that the antenna 500 is exposed to the outside may be formed. That is, as illustrated in FIGS. 5 to 7, the stand 510 and the locking part 600 are not exposed to the outside by the upper surface of the upper cover 520, while the antenna 500 may be exposed to the outside by the accommodation space 521 of the upper cover 520.

Therefore, the antenna 500 of the charging device 1000 according to the embodiments has an effect of improving aesthetics in appearance while maintaining the wireless radiation function by the accommodation space 521 formed in the upper cover 520.

More specifically, as shown in FIGS. 6 and 7, the upper cover 520 may include an antenna hole 5221 provided to form a step difference with the upper surface of the upper cover 5221 and an inclined surface 5222 formed to extend from a circumference forming the antenna hole 5221 to the upper surface of the upper cover 520 in an outward direction. That is, the accommodation space 521 may be formed by the antenna hole 5221 and the inclined surface 5222.

The antenna hole 5221 may be formed in the same plane as the lower portion of the antenna 500. That is, a distance from the upper surface of the antenna 500 to the antenna hole 5221 may be the same as the height of the antenna 500. Likewise, a distance from the upper surface 101 of the main body 100 to the antenna hole 5221 may be the same as the height of the stand 510.

The inclined surface 5222 may be formed to be inclined. That is, the inclined surface 5222 may be obliquely extended from the circumference forming the antenna hole 5221 to the upper surface of the upper cover 520 in an outward direction. In this case, the outward direction may refer to an outward direction with respect to the main body 100. Wireless radiation generated by the antenna 500 may not be disturbed by the upper cover 520 owing to the inclination of the inclined surface 5222.

As shown in FIG. 6, the accommodation space 521 may be formed in a truncated conical shape. That is, a cross-sectional area of the accommodation space 521 may increase from a lower portion toward an upper portion.

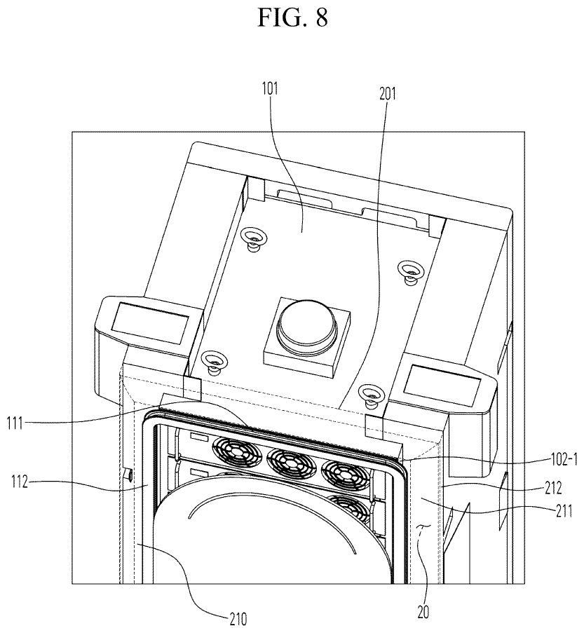

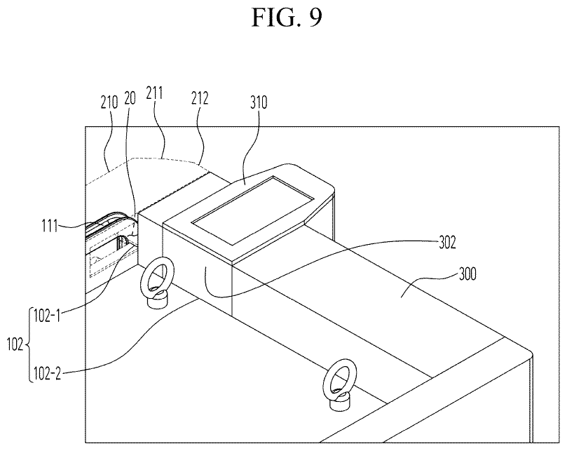

FIGS. 8 and 9 are diagrams illustrating a second space of a charging device according to embodiments.

FIG. 9 is a diagram of FIG. 8 viewed from a rear direction.

Referring to FIGS. 8 and 9, the front door 200 may include a door part 210, an inclined part 211, and a bent part 212.

The door part 210 may be formed in a plate shape coupled to a front surface of the main body 100. The upper surface 201 of the door part 210 may correspond to the upper surface 201 of the front door 200.

The bent part 212 may be formed to extend from both sides of the door part 210 in a direction surrounding portions of both side surfaces 102 of the main body 100. According to embodiments, the inclined part 211 having a predetermined inclination may be formed between the bent part 212 and the door part 210.

The side surface 102 of the main body 100 may include a first side surface 102-1 covered by the bent part 212 and a second side surface 102-2 covered by the side cover 300. In this case, the bent part 212 may be formed to be spaced apart from the first side surface 102-1 by a predetermined distance, and the side cover 300 may be formed such that an inner side surface 302 thereof contacts the second side surface 102-2.

In addition, the bent part 212 is formed to be spaced apart from the first side surface 102-1 by a predetermined distance, thereby forming a second space 20. That is, the second space 20 may be formed by the door part 210, the inclined part 211, the bent part 212, and the first side surface 102-1 of the main body 100.

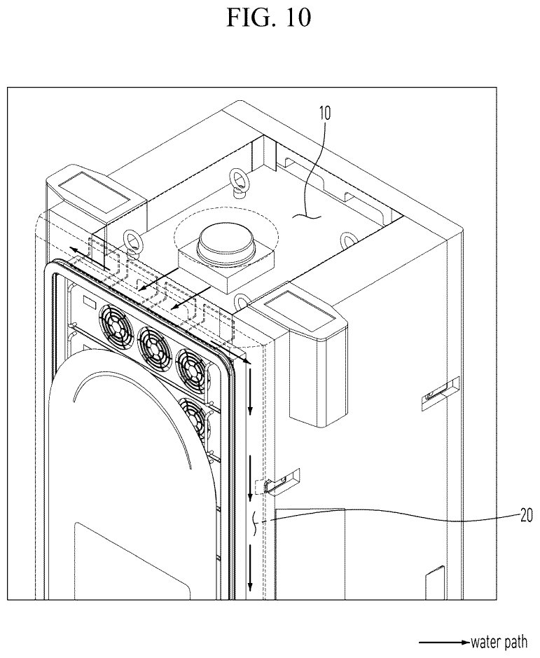

Also, the upper surface 201 of the door part 210 may be formed to be spaced apart from the upper surface 101 of the main body 100 by a predetermined distance. Accordingly, the first space 10 (see FIGS. 3 and 4) formed by the upper surface 101 of the main body 100 and the second space 20 formed by the first side surface 102-1 of the main body 100 may be connected to each other. Moisture or the like present in the first space 10 may be discharged through the second space 20. A detailed description thereof will be described with reference to FIG. 10.

A front surface of the main body 100 may include an upper edge and a side edge forming an edge. In other words, the upper edge may be located at an upper portion of a front edge of the main body 100, and the side edge may be located at both sides of the front edge of the main body.

The upper edge and the side edge may be formed with preventive projections 111 and 112 protruding at a predetermined height from the upper surface 101 of the main body 100 and the side surface 102 of the main body 100, respectively. That is, the upper edge may include an upper preventive projection 111 protruding at a predetermined height in an upward direction with respect to the upper surface 101 of the main body 100, and the side edge may include a side preventive projection 112 protruding at a predetermined height in a left or right direction with respect to the side surface 102 of the main body 100.

Also, the preventive projections 111 and 112 may be formed of a sealing member. That is, the preventive projections 111 and 112 may include a sealing member formed along the preventive projections 111 and 112, or may be formed of a sealing member.

FIG. 10 is a diagram illustrating a path on which water moves along a second space of a charging device according to embodiments.

A first space 10 shown in FIG. 10 corresponds to the first space 10 shown in FIGS. 3 and 4. A second space 20 shown in FIG. 10 corresponds to the second space 20 shown in FIGS. 8 and 9.

Referring to FIG. 10, water accumulated in the first space 10 due to rain, snow, etc. may not continue to accumulate in the first space 10 and may move through the second space 20 connected to the first space 10. In particular, even when the upper cover 520 is coupled, moisture may be introduced into the first space 10 through the accommodation space 521.

The charging device 1000 according to the embodiments may be a kind of charger for an electric vehicle as described in FIGS. 1 and 2, in particular, a kind of charger dispenser provided outdoors. Therefore, water may be accumulated in the first space 10 by the charging device 1000 provided outdoors when it snows or rains. Particularly, even when the upper cover 520 is coupled, moisture may be introduced into the first space 10 through the accommodation space 521.

Accordingly, the charging device 1000 according to embodiments may form the second space 20 connected to the first space 10 to prevent water from accumulating in the first space 10. The description of the second space 20 is the same as that described in FIGS. 8 and 9, and thus will be omitted.

That is, referring to FIG. 10, water accumulated in the first space 10 moves downward along the second space 20 formed by the side surface 102 of the main body 100. Therefore, even when it rains or snows a lot, water is not accumulated in the first space 10 where the antenna 500 of the charging device 1000 according to embodiments is located.

In addition, as described in FIGS. 3 and 4, a portion of the upper surface of the stand 510 that meets the lower portion of the antenna 500 and a portion of the upper surface of the main body 100 that meets the lower portion of the stand 510 are made up of the sealing members 501 and 511, respectively, so the sealing members 501 and 511 of the charging device 1000 according to the embodiments may prevent the occurrence of damage caused to the antenna 500 due to moisture even when water penetrates into the first space 10.

Likewise, as described in FIGS. 8 and 9, since the upper and side edges of the front edge among the edges forming the front flange of the main body 100 are formed with the preventive projections 111 and 112 made of sealing members, respectively, the preventive projections 111 and 112 of the charging device 1000 according to the embodiments may prevent damage to the main body 100 and the front door 200 due to moisture even when water moves along the first and second spaces 10 and 20.

Therefore, the charging device 1000 according to embodiments may prevent damage caused by moisture.

FIG. 11 is a diagram illustrating a lower portion of a charging device according to embodiments. More specifically, FIG. 11 (a) is a diagram illustrating a lower portion of a charging device excluding a front door according to embodiments, and FIG. 11 (b) is a diagram illustrating a lower portion of a charging device in a state where a front door of a charging device is coupled thereto according to embodiments.

Referring to FIG. 1 and FIG. 11 together, the support part 700 is coupled to a lower portion of the main body 100 and fixes the main body 100 to the ground, and a discharge hole 701 may be formed in an area that contacts the front door 200. A plurality of discharge holes 701 may be formed, as shown in FIG. 11 (a). More specifically, the discharge hole 701 may be connected to the second space 20 formed by the front door 200 and the side surface 102 of the main body 100.

Namely, as described in FIG. 10, the water having accumulated in the first space 10 moves downward through the second space 20. And as a result, the water may be collected in an inside of the front door 200, i.e., in a lower portion of a space formed by the door part 210, the bent part 212, and the side surface 102. Accordingly, the charging device 1000 according to the embodiments may discharge the water collected in the lower portion to the outside through the discharge hole 701.

Referring to FIG. 11, the discharge hole 701 may not be exposed to the outside by the front door 200. That is, the discharge hole 701 may be formed in an area of the support part 700 that is in contact with a lower surface of the front door 200. Therefore, the discharge hole 701 may not be exposed to the outside by the appearance of the door part 210, the inclined part 211, and the bent part 212 of the front door 200.

The detailed description of the preferred embodiments of the present disclosure disclosed as described above has been provided to allow those skilled in the art to embody and implement the present disclosure. Although the above has been described with reference to the preferred embodiments of the present disclosure, those skilled in the art will understand that the present disclosure may be variously modified and changed without departing from the scope of the present disclosure. For example, those skilled in the art may use each of the components described in the above-described embodiments in a manner of combining them with each other.

Therefore, the present disclosure is not intended to be limited to the embodiments shown here, but to give a maximum scope consistent with the principles and new features disclosed herein.

What is claimed is:

1. A charging device, comprising:
a main body having a cable connected charger located therein;
a front door covering a front surface of the main body and portions of both side surfaces of the main body;
a pair of side covers covering the rest of the both side surfaces of the main body;
a rear cover covering a rear surface of the main body; and
an antenna disposed on an upper surface of the main body,
wherein the upper surface of the main body is formed lower than upper surfaces of the front door, the pair of the side covers, and the rear cover.

2. The charging device of claim 1, wherein the upper surfaces of the front door, the pair of the side covers, and the rear cover are formed in a same plane.

3. The charging device of claim 1, further comprising a stand coupled to the upper surface of the main body and having a height to support a lower portion of the antenna, wherein a sum of the height of the stand and a height of the antenna is equal to a height from the upper surface of the main body to the upper surface of the front door, the pair of the side covers, or the rear cover.

4. The charging device of claim 3, wherein a portion of the upper surface of the stand meeting the lower portion of the antenna and a portion of the upper surface of the main body meeting a lower portion of the stand include a sealing member.

5. The charging device of claim 1, further comprising a first space formed by the upper surface of the main body and inner surfaces of the front door, the pair of the side covers, and the rear cover.

6. The charging device of claim 1, further comprising an upper cover disposed on the main body and having an accommodation space for receiving the antenna therein to expose the antenna externally.

7. The charging device of claim 6, the upper cover comprising:
an antenna hole formed to make a step difference from an upper surface of the upper cover; and
an inclined surface extending from a circumference forming the antenna hole to the upper surface of the upper cover toward an outer direction,
wherein the accommodation space is formed by the antenna hole and the inclined surface.

8. The charging device of claim 7, wherein the antenna hole is formed in a same plane with the lower portion of the antenna.

9. The charging device of claim 1, the front door comprising:
a door part in a plate shape coupled to a front surface of the main body; and
a bent part extending from both sides of the door part in a direction of surrounding the both side surfaces of the main body,
wherein the bent part is spaced apart from the side surface of the main body.

10. The charging device of claim 9, further comprising a second space formed by the door part, the bent part and the side surface of the main body.

11. The charging device of claim 1, wherein an upper edge and side edges of the both sides forming a flange of the front surface of the main body include preventive projections protruding from the upper surface of the main body and the side surface of the main body, respectively.

12. The charging device of claim 11, wherein the preventive projection comprises a sealing member.

13. The charging device of claim 1, further comprising a locking part located on the upper surface of the main body.

14. The charging device of claim 1, further comprising a support part coupled to the lower portion of the main body, wherein the support part comprises a discharge hole formed in an area meeting the front door not to be externally exposed by the front door.
